(19) United States
(12) Patent Application Publication
(10) Pub. No.: US 2008/0308889 A1
(43) Pub. Date: Dec. 18, 2008

(54) Image sensing module and method for packaging the same

(76) Inventors: Chia-Shuai CHANG, Tao-Yuan Hsien (TW); Cheng-Lung CHUANG, Tao-Yuan Hsien (TW); Chia-Ming WU, Tao-Yuan Hsien (TW)

Correspondence Address: BACON & THOMAS, PLLC, 625 SLATERS LANE, FOURTH FLOOR, ALEXANDRIA, VA, 22314-1176, US

(21) Appl. No.: 12/153,198

(22) Filed: May 15, 2008

Related U.S. Application Data
(62) Division of application No. 11/585,917, filed on Oct. 25, 2006.

(51) Int. Cl. H01L 31/0203

(52) U.S. Cl. 257/434; 257/E31.11

(57) ABSTRACT

An image sensing module and a method for packaging the same are disclosed. Meanwhile, the packaging method includes the steps of a) providing a substrate; b) forming plural passive devices on the substrate; c) adhering a chip on the substrate and bonding thereon; d) providing a ring frame, wherein the ring frame includes an opening window and plural pillars for contacting with the substrate; e) adhering a glass piece on the opening window to form a lid assembly; f) covering the lid assembly on the substrate, wherein the plural pillars contacting with the substrate, the plural passive devices and the chip are covered by the lid assembly, and plural gaps are formed between the ring frame and edges of the substrate; and g) filling a filler into the plural gaps to seal the plural passive devices and the chip in the lid assembly and the substrate.

### FIELD OF THE INVENTION

The present invention relates to an image sensing module and a method for packaging the same.

### BACKGROUND OF THE INVENTION

The package technology keeps on improving by using miniaturization as design criterion in accordance with the application in the light of heat dissipation through dense array packages applied into commercial semiconductors. Image sensor packages are typically formed by mounting a plurality of sensor chips in a rectangular array on a substrate tile (e.g., a ceramic tile). After wire bonding, a lattice of “dam” walls is formed using liquid epoxy between the adjacent chips so that each chip is surrounded on all four sides by a wall of epoxy. A glass sheet is then adhered to the tops of the dam walls and encapsulates each chip in isolation from the surrounding chips. The entire assembly is then baked to harden the epoxy walls and cut along the lines of the walls between adjacent sensors to produce a plurality of individual, encapsulated sensor devices. To protect the image sensor, it is necessary that the image sensor be packaged in a controlled environment, with minimum amounts of moisture, adhesives, dust, and other contaminants. In order to provide such an environment, hermetically sealed packages are often used. However, the cost of such packages and the negative impact on the assembly process is extremely high.

The packaging of image sensor chips for use in projection display and other electro-optical applications has continued to present a cost barrier that contributes to higher prices for these products. A lower cost image sensor package is required to reduce the cost of these high-resolution, digital projectors. Today's image sensor packages are mostly built on custom designed ceramic substrates and have expensive glass covers (lids), which are seam welded or fixed in place with an adhesive. These packages are not only expensive, but they require a low throughput process that reduces the product cycle time.

FIGS. 1(A)-1(F) illustrate a packaging process according to the prior art. As shown in FIG. 1(A), a substrate 10 is provided, wherein the substrate 10 could be a ceramic or a PCB. In FIG. 1(B), plural passive device 11 could be disposed on the substrate 10 and formed a circuit. Then, a chip 13 is attached to the substrate 10, wherein the chip 13 has plural leads to be bounded to pads of the substrate 10, which extend to external package pads on the edges or bottom of the package, as show in FIG. 1(C). On the other hand, a lid assembly is provided, which consists of a ring frame 14 with built-in an optical quality glass window 15. Meanwhile, the ring frame 14 is provided as shown in FIG. 1(D); and then the optical quality glass window 15 is adhered on the ring frame 14 to form a lid assembly, as shown in FIG. 1(E). Finally, the lid assembly of the ring frame 14 and the optical quality glass widows 15 further covers on the structure of FIG. 1(C), the package is filled with an inert gas; and then the lid assembly is seam welded. In practice, there should be two mating surfaces between the ring frame 14 and the substrate 10. Meanwhile, the ring frame 14 occupies the entire ring surface of the substrate 10. For minimization, the substrate 10 should be utilized efficiently. If the entire ring surface of the substrate 10 is occupied, the entire surface of the substrate should be reduced. Therefore, the residue surface of the substrate 10 for plural passive device 11 and the chip 13 is limited, thereby being disadvantageous for minimization.

Although image sensing modules for use in optical applications are technically feasible, in practice they are very difficult to implement. The packages discussed above perform very well but are too expensive and tend to limit cost reduction efforts due to their high cost material and labor content. What is needed is a simple packaging approach that is low cost, easily assembled, and reliable. The invention disclosed herein fulfills this need. Therefore, it needs to provide an image sensing module and a method for packaging the same, which introduce a specific ring frame without occupying the entire ring surface of the substrate for facilitating to minimization, and can rectify those drawbacks of the prior art and solve the above problems.

### SUMMARY OF THE INVENTION

This paragraph extracts and compiles some features of the present invention; other features will be disclosed in the follow-up paragraph. It is intended to cover various modifications and similar arrangements included within the spirit and scope of the appended claims, and this paragraph also is considered to refer.

Accordingly, the prior art is limited by the above problems. It is an object of the present invention to provide A method for packaging an image sensing module, which introduce a specific ring frame without occupying the entire ring surface of the substrate for facilitating to minimization, and can rectify those drawbacks of the prior art and solve the above problems.

In accordance with an aspect of the present invention, the method for packaging an image sensing module includes the steps of: a) providing a substrate; b) forming plural passive devices on the substrate; c) adhering a chip on the substrate and bonding thereon; d) providing a ring frame, wherein the ring frame includes an opening window and plural pillars for contacting with the substrate; e) adhering a glass piece on the opening window to form a lid assembly; f) covering the lid assembly on the substrate, wherein the plural pillars contacting with the substrate; the plural passive devices and the chip are covered by the lid assembly; and plural gaps are formed between the ring frame and edges of the substrate; and g) filling a filler into the plural gaps to seal the plural passive devices and the chip in the lid assembly and the substrate.

Certainly, the filler can be an epoxy resin.

Preferably, the substrate is one of a ceramic substrate and a PCB.

Preferably, the chip is bonded on the substrate through plural wires.

Preferably, the step b) is executed by means of surface mounting technology (SMT).

Certainly, the plural pillars can be disposed around four comers of the ring frame.

In accordance with another aspect of the present invention, the method for packaging an image sensing module includes the steps of: a) providing a substrate; b) providing a lid assembly having a ring frame with an opening window and plural pillars for contacting with the substrate; c) covering the lid assembly on the substrate, wherein the plural pillars contacting with the substrate; and plural gaps are formed around edges of the substrate; and d) filling a filler into the plural gaps.

Preferably, the substrate further includes plural passive devices and a chip disposed thereon.

Certainly, the chip can be bonded on the substrate through plural wires.

Preferably, the plural passive devices are disposed on the substrate by means of surface mounting technology (SMT).

Preferably, the substrate is one of a ceramic substrate and a PCB.

Preferably, the lid assembly further includes a glass piece disposed on the opening window to form the lid assembly.

Certainly, the filler can be an epoxy resin.

Preferably, the plural pillars are disposed around four comers of the lid assembly.

It is another object of the present invention to provide an image sensing module for use in optical applications, which introduce a specific ring frame without occupying the entire ring surface of the substrate for facilitating to minimization, and can rectify those drawbacks of the prior art and solve the above problems.

In accordance with an aspect of the present invention, the image sensing module for use in optical applications includes a substrate having plural passive devices and a chip disposed thereon; a lid assembly having a ring frame with an opening window and plural pillars, wherein the plural pillars contacts with edges of the substrate to form plural gaps around edges of the substrate; a glass piece disposed in the opening widow to cover the substrate; and a filler filled into the plural gaps around edges of the substrate.

Certainly, the chip can be bonded on the substrate through plural wires.

Preferably, the plural passive devices are disposed on the substrate by means of surface mounting technology (SMT).

Preferably, substrate is one of a ceramic substrate and a PCB.

Certainly, the filler can be an epoxy resin.

Preferably, the plural pillars are disposed around four comers of the lid assembly.

The above objects and advantages of the present invention will become more readily apparent to those ordinarily skilled in the art after reviewing the following detailed description and accompanying drawings, in which:

### BRIEF DESCRIPTION OF THE DRAWING

FIGS. 1(A)-1(F) illustrate an image sensing module packaging process according to the prior art;

FIGS. 2(A)-2(G) illustrate an method for packaging an image sensing module according to the present invention;

FIGS. 3(A)-3(D) illustrate another simple method for packaging an image sensing module according to the present invention;

FIG. 4 illustrates an image sensing module according to the present invention.

### DETAILED DESCRIPTION OF THE PREFERRED EMBODIMENTS

The present invention will now be described more specifically with reference to the following embodiments. It is to be noted that the following descriptions of preferred embodiments of this invention are presented herein for purpose of illustration and description only; it is not intended to be exhaustive or to be limited to the precise form disclosed.

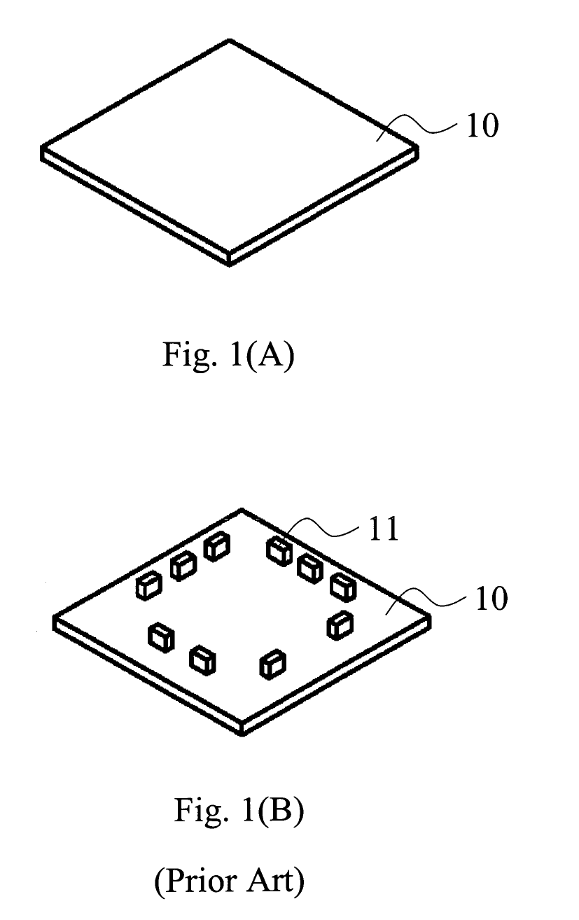

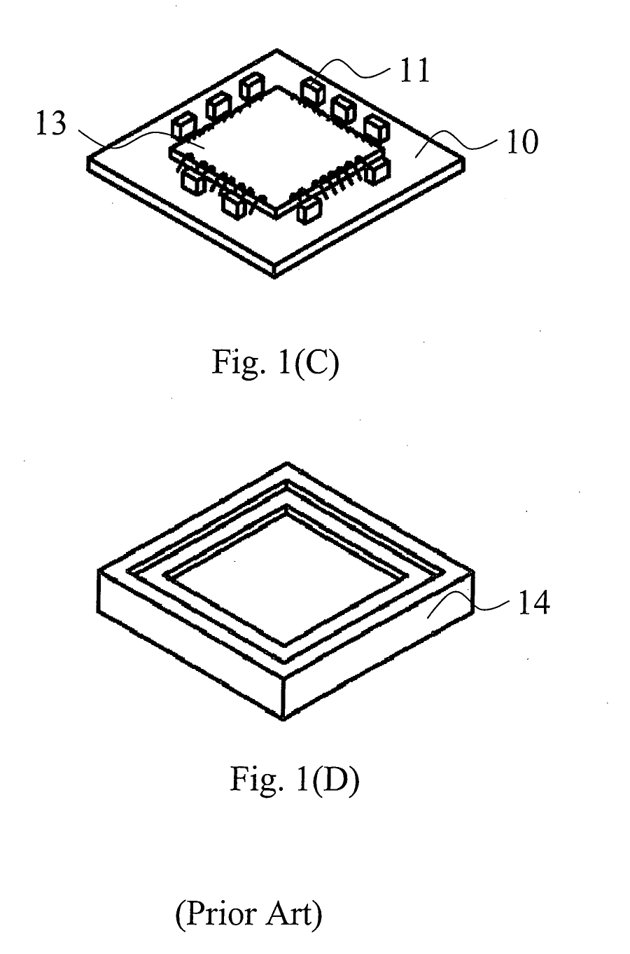

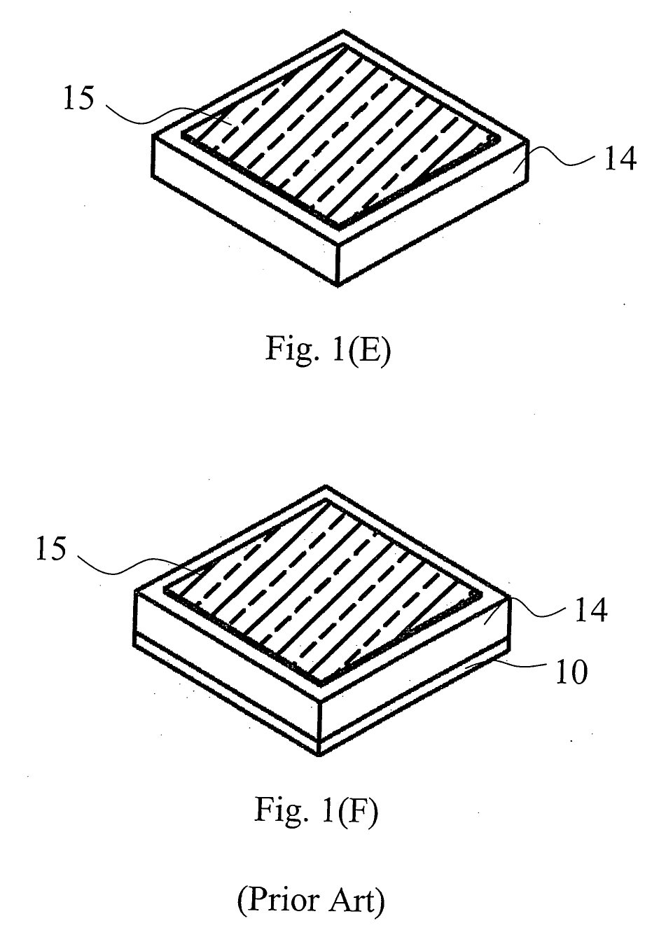

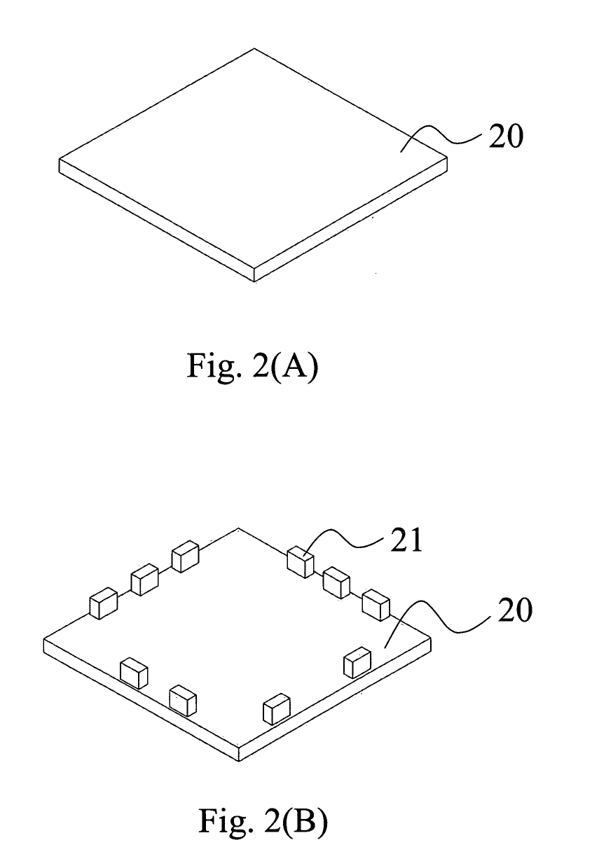

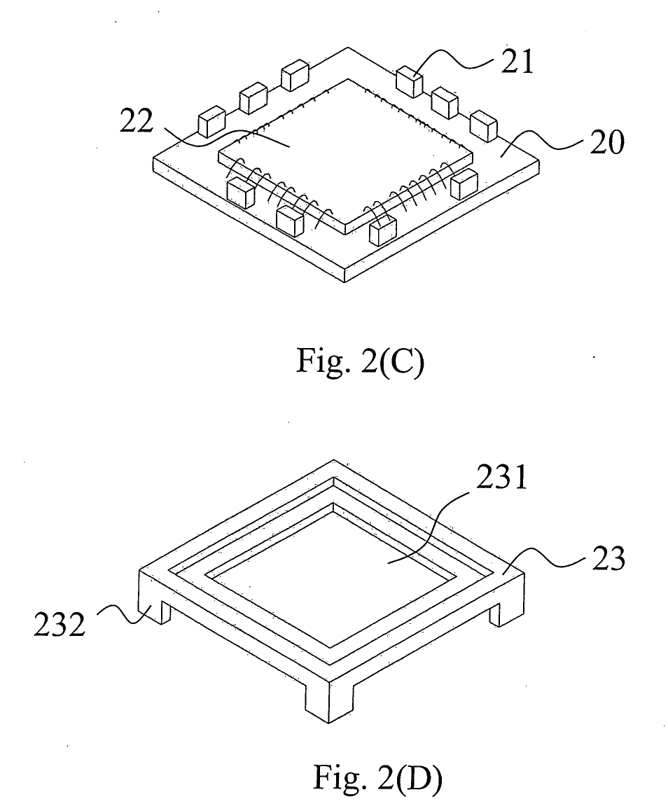

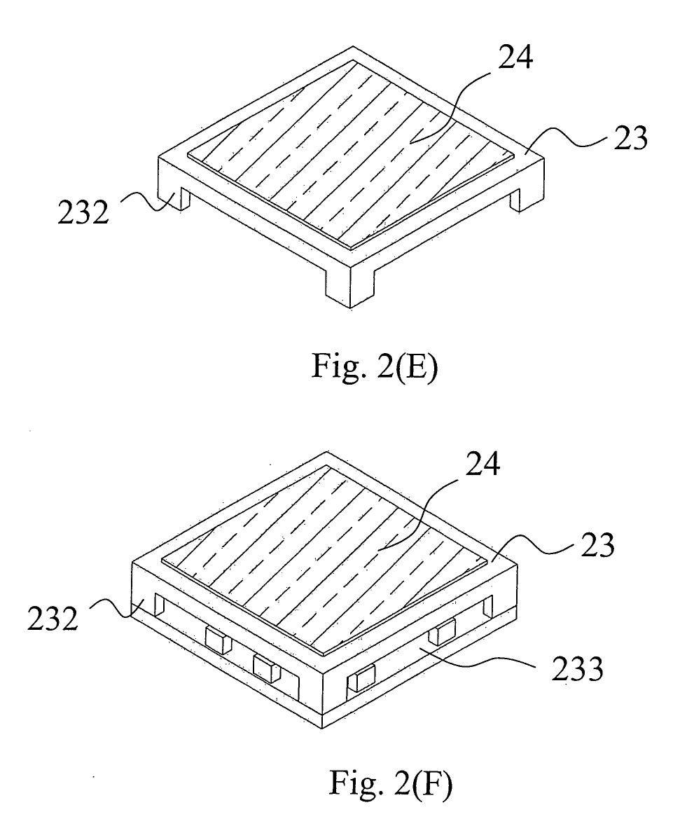

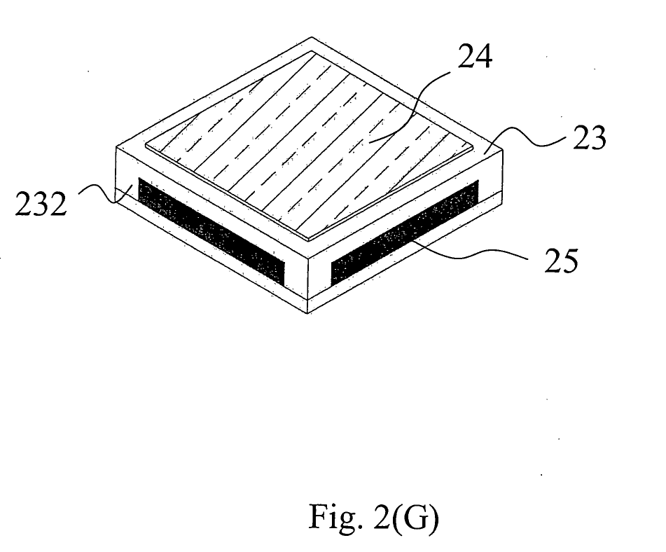

Please refer to FIGS. 2(A)-2(G). They illustrate a method for packaging an image sensing module according to the present invention. The packaging method includes the steps of: a) providing a substrate 20, as shown in FIG. 2(A), wherein the substrate could be a ceramic substrate or a PCB; b) forming plural passive devices 21 on the substrate 20 by means of surface mounting technology (SMT), as shown in FIG. 2(B); c) adhering a chip 22 on the substrate 20 and bonding thereon, as shown in FIG. 2(C), wherein the chip 22 is bonded on the substrate 20 through plural wires 22; d) providing a ring frame 23, wherein the ring frame 23 includes an opening window 231 and plural pillars 232 for contacting with the substrate 20, as shown in FIG. 2(D); e) adhering a glass piece 24 on the opening window 231 to form a lid assembly as shown in FIG. 2(E); f) covering the lid assembly on the substrate 20, as shown in FIG. 2(F), wherein the plural pillars 232 contacting with the substrate 20; the plural passive devices 21 and the chip 22 are covered by the lid assembly; and plural gaps 233 are formed between the ring frame 23 and edges of the substrate 20; and g) filling a filler 25 into the plural gaps 233 to seal the plural passive devices 21 and the chip 22 in the lid assembly and the substrate 20, as shown in FIG. 2(G). In this embodiment, the filler 25 can be made from an epoxy resin. On the other hand, the plural pillars 232 are disposed around four corners of the ring frame 23. Accordingly, the seal package method for use in optical applications introduces a specific ring frame without occupying the entire ring surface of the substrate for facilitating to minimization. Obviously, the specific ring frame 23 of the present invention don't have round wall as shown in FIG. 1(D); and the substrate 20 of the present invention could provide more surface for plural passive devices and the chip, thereby facilitating to minimization.

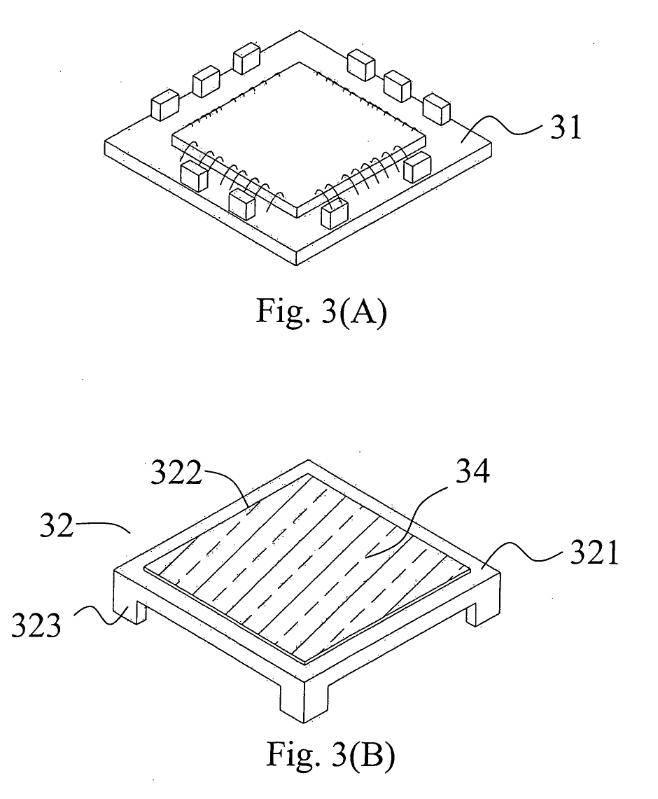

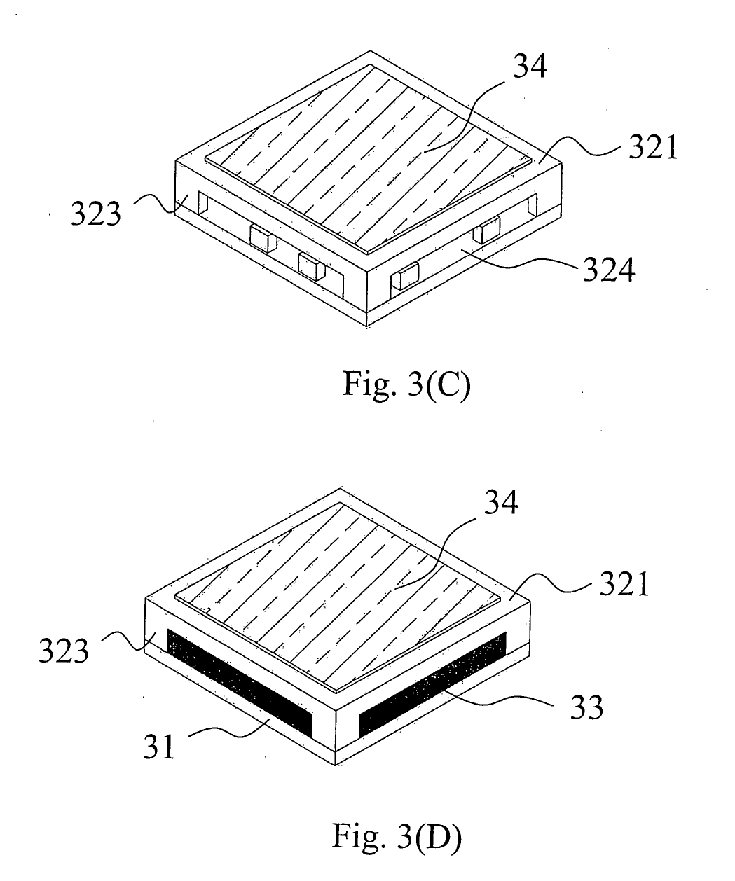

Please refer to FIG. 3(A)-3(D). They illustrate another simple method for packaging an image-sensing module according to the present invention. The packaging method includes the steps of: a) providing a substrate 31, as shown in FIG. 3(A); b) providing a lid assembly 32 having a ring frame 321 with an opening window 322 and plural pillars 323 for contacting with the edged surface of the substrate 31, as shown in FIG. 3(B), wherein a glass piece 34 is disposed in the opening window 322; c) covering the lid assembly 32 on the substrate 31, wherein the plural pillars 323 contacting with the edged surface of the substrate 31, as shown in FIG. 3(C); and plural gaps 324 are formed around edges of the substrate 31; and d) filling a filler 33 into the plural gaps 324 as shown in FIG. 3(D).

In practice, the filler 33 can be made from an epoxy resin. The lid assembly 32 has four pillars 323 disposed around four corners of the lid assembly 32. Accordingly, the seal package method for use in optical applications introduces a specific ring frame merely occupying four corners without occupying the entire ring surface of the substrate for facilitating to minimization. Obviously, the specific ring frame 321 of the present invention don't have round wall as shown in FIG. 1(D); and the substrate 31 of the present invention could provide more surface for other devices or chips, thereby facilitating to minimization.

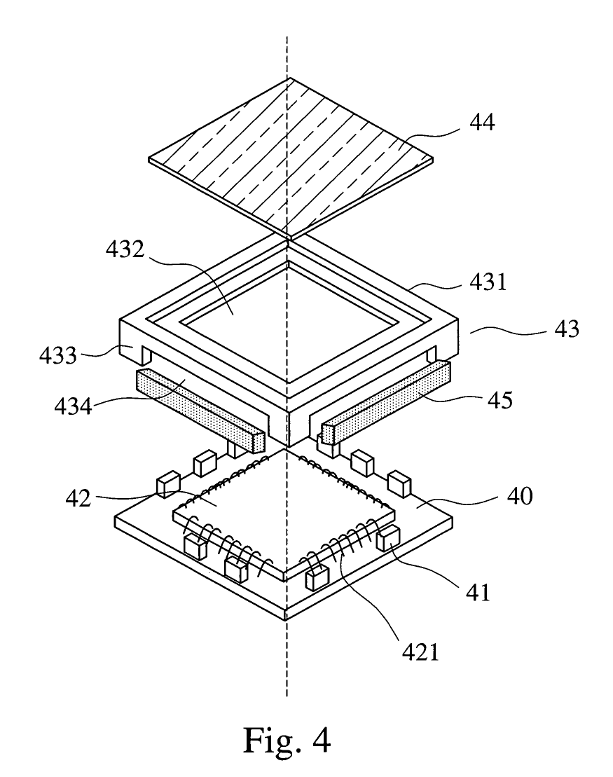

According to the above method, the present invention further discloses an image-sensing module for use in optical applications. Please refer to FIG. 4. It illustrates an image-sensing module for use in optical applications according to the present invention. The image sensing module includes a substrate 40 having plural passive devices 41 and a chip 42 disposed thereon; a lid assembly 43 having a ring frame 431 with an opening window 432 and plural pillars 433, wherein the plural pillars 433 contacts with edges of the substrate to form plural gaps 434 around edges of the substrate 40; a glass piece 44 disposed in the opening widow 432 to cover the substrate 40; and a filler 45 filled into the plural gaps 434 around edges of the substrate 40 as shown in FIG. 4.

In practice, the chip 42 can be bonded on the substrate 40 through plural wires 421. On the other hand, the plural passive devices 41 are disposed on the substrate 40 by means of surface mounting technology (SMT). Preferably, the substrate 40 of the present invention can be a ceramic substrate or a PCB. Moreover, the filler 45 is made from an epoxy resin. Accordingly, the image-sensing module introduces a specific ring frame without occupying the entire ring surface of the substrate for facilitating to minimization. In this embodiment, the lid assembly 43 has four pillars 433 disposed around four corners of the lid assembly 43 merely, instead of occupying the entire ring surface of the substrate. Therefore, the image-sensing module could provide more surface area for disposing devices, thereby facilitating to minimization.

In conclusion, the present invention provides an image sensing module and a method for packaging the same, which introduces a specific ring frame without occupying the entire ring surface of the substrate for facilitating to minimization. Obviously, the specific ring frame of the present invention don't have round wall as the prior art; and the substrate of the present invention could provide more surface for plural devices, thereby facilitating to minimization, but the prior art fail to disclose that. Accordingly, the present invention possesses many outstanding characteristics, effectively improves upon the drawbacks associated with the prior art in practice and application, bears novelty, and adds to economical utility value. Therefore, the present invention exhibits a great industrial value.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims, which are to be accorded with the broadest interpretation so as to encompass all such modifications and similar structures.

What is claimed is:

1. An image sensing module, comprising:
a substrate having plural passive devices and a chip disposed thereon;
a lid assembly having a ring frame with an opening window and plural pillars, wherein said plural pillars contacts with edges of said substrate to form plural gaps around edges of said substrate;
a glass piece disposed in said opening widow to cover said substrate; and
a filler filled into said plural gaps around edges of said substrate.

2. The image sensing module according to claim 1, wherein said chip is bonded on said substrate through plural wires.

3. The image sensing module according to claim 1, wherein said plural passive devices are disposed on said substrate by means of surface mounting technology (SMT).

4. The image sensing module according to claim 1, wherein said substrate is one of a ceramic substrate and a PCB.

5. The image sensing module according to claim 1, wherein said filler is an epoxy resin.

6. The image sensing module according to claim 1, wherein said plural pillars are disposed around four corners of said lid assembly.
